(19) United States
(12) Patent Application Publication
(10) Pub. No.: US 2024/0112892 A1
(43) Pub. Date: Apr. 4, 2024

(54) PLASMA PROCESSING APPARATUS AND PLASMA PROCESSING METHOD

(71) Applicant: Panasonic Intellectual Property Management Co., Ltd., Osaka (JP)

(72) Inventor: Pei YE, OSAKA (JP)

(21) Appl. No.: 18/467,775

(22) Filed: Sep. 15, 2023

(30) Foreign Application Priority Data
Sep. 22, 2022 (JP) 2022-151319

(51) Int. Cl. H01J 37/32

(52) U.S. Cl. CPC H01J 37/32715; H01J 37/32458; H01J 37/32733

(57) ABSTRACT

A plasma processing apparatus 10 includes: a first support member 81 for raising and lowering an object to be processed 200, a second support member 82 supporting a cover 70, a drive part 120 for raising and lowering the cover 70 via the second support member 82. The drive part 120, when raising the cover 70 from a lowered position to a raised position, in a first process, raises the second support member 82 without raising the first support member 81, and thus to raise the cover 70 without raising the object to be processed 200, and in a second process, raises the first and second support members 81 and 82 integrally, and thus to raise the cover 70 from the beginning of the second process, and raise the object to be processed 200 from the beginning of or after the beginning of the second process.

### CROSS REFERENCE TO RELATED APPLICATION

The present application is based on and claims priority under 35 U.S.C. § 119 with respect to the Japanese Patent Application No. 2022-151319 filed on Sep. 22, 2022, of which entire content is incorporated herein by reference into the present application.

### TECHNICAL FIELD

The present disclosure relates to a plasma processing apparatus and a plasma processing method.

### BACKGROUND

Conventionally, a plasma processing apparatus for performing a plasma processing on an object to be processed has been known as disclosed in Patent Literature 1 (JP5906429B). The plasma processing apparatus of Patent Literature 1 includes a stage on which an object to be processed is placed, a cover disposed above the stage and covering the outer edge portion of the object to be processed on the stage, a first lifting member for raising and lowering the object to be processed, and a second lifting member for raising and lowering the cover, in which the first lifting member and the second lifting member are raised and lowered integrally.

In the plasma processing apparatus of Patent Literature 1, however, in a state where the first and second lifting members are lowered to perform a plasma processing, a space is formed between the first lifting member and the object to be processed (or below the object to be processed). Such a space, if any, may lead to the occurrence of an abnormal discharge during the plasma processing on the object to be processed. Under such circumstances, one of the objectives of the present disclosure is to make an abnormal discharge unlikely to occur.

### SUMMARY

One aspect of the present disclosure relates to a plasma processing apparatus. The plasma processing apparatus includes: a chamber in which a plasma processing on an object to be processed is performed; a stage which is disposed in the chamber and on which the object to be processed is placed; a cover disposed above the stage and covering an outer edge portion of the object to be processed; a first support member disposed so as to penetrate the stage, and configured such that an upper end of the first support member protrudes from the stage to support the object to be processed, to raise and lower the object to be processed; a second support member supporting the cover, to raise and lower the cover; and a drive part configured to raise and lower the cover supported by the second support member, between a lowered position and a raised position, by driving the second support member; wherein the drive part, when raising the cover from the lowered position to the raised position, in a first process in which the cover is raised from the lowered position until reaching an intermediate position between the lowered position and the raised position, raises the second support member without raising the first support member, and thus to raise the cover without raising the object to be processed, and in a second process in which the cover is raised from the intermediate position until reaching the raised position, raises the first support member and the second support member integrally, and thus to raise the cover from a beginning of the second process, and raise the object to be processed from the beginning of the second process or after the beginning of the second process.

Another aspect of the present disclosure relates to a plasma processing method. The plasma processing method is performable in a plasma processing apparatus including: a chamber in which a plasma processing on an object to be processed is performed; a stage which is disposed in the chamber and on which the object to be processed is placed; a cover disposed above the stage and covering an outer edge portion of the object to be processed placed on the stage; a first support member disposed so as to penetrate the stage, and configured such that an upper end of the first support member protrudes from the stage to support the object to be processed, to raise and lower the object to be processed; and a second support member supporting the cover, to raise and lower the cover, the method comprising: a processing process of performing a plasma processing on the object to be processed placed on the stage; and a raising process of raising the cover supported by the second support member from a lowered position to a raised position, by driving the second support member, wherein the raising process has a first step of raising the second support member without raising the first support member, until the cover reaches from the lowered position to an intermediate position between the lowered position and the raised position, thus to raise the cover without raising the object to be processed, and a second step of raising the first support member and the second support member integrally, until the cover reaches from the intermediate position to the raised position, thus to raise the cover from a beginning of the second step, and raise the object to be processed from the beginning of the second step or after the beginning of the second step.

According to the present disclosure, an abnormal discharge can be made unlikely to occur.

### BRIEF DESCRIPTION OF THE DRAWINGS

FIG. 1 is a schematic cross-sectional view of a plasma processing apparatus of Embodiment 1.

FIGS. 2A to 2C show cross-sectional views of an essential part of the plasma processing apparatus, where FIG. 2A illustrates a state in which a cover is in a lowered position, FIG. 2B illustrates a state in which the cover is in an intermediate position, and FIG. 2C illustrates a state in which the cover is in a raised position.

FIG. 3 is a schematic cross-sectional view of a plasma processing apparatus of Embodiment 2.

### DETAILED DESCRIPTION

Embodiments of a plasma processing apparatus and a plasma processing method according to the present disclosure will be described below by way of examples. It is to be noted, however, that the present disclosure is not limited to the examples described below. In the description below, specific numerical values and materials are exemplified in some cases, but other numerical values and materials may be applied as long as the effects of the present disclosure can be achieved.

(Plasma Processing Apparatus)

A plasma processing apparatus according to the present disclosure may be, for example, a plasma etching apparatus, a plasma cleaning apparatus, a plasma dicer, a plasma ashing apparatus, or a plasma CVD apparatus. The plasma processing apparatus according to the present disclosure includes a chamber, a stage, a cover, a first support member, a second support member, and a drive part.

The chamber is configured to perform a plasma processing on an object to be processed, in its inside. The chamber may be formed in a hollow cylinder shape having an opening at the top. The opening of the chamber may be closed with a dielectric member. Above the dielectric member, a coil for generating a plasma within the chamber may be disposed.

The stage is provided in the chamber, and an object to be processed is placed thereon. The stage may have a horizontal placement surface for placing the object to be processed thereon. The stage may have a channel for flowing a coolant for cooling the object to be processed during the plasma processing. The stage may have an electrostatic chuck system for chucking the object to be processed. The stage may have a lower electrode to be applied with a high-frequency power. The object to be processed may be, for example, a semiconductor substrate to be diced into individual chips by plasma etching. The semiconductor substrate includes a plurality of element regions and dicing regions defining the element regions. The element regions include, for example, a semiconductor layer and a wiring layer. By etching the dicing regions, element chips having a semiconductor layer and a wiring layer can be obtained. The object to be processed may be supported on a carrier, and in this state, may be placed on the stage. The carrier may be, for example, a holding sheet with the outer peripheral portion held by a frame.

The cover is disposed above the stage. The cover is covering an outer edge portion of the object to be processed placed on the stage. The cover has a window area where, of the object to be processed placed on the stage, a portion subjected to a plasma processing is exposed. In the state during the plasma processing, the distance (minimum vertical distance) between the cover and the object to be processed may be, for example, 1 mm or more and 4 mm or less.

The first support member is disposed so as to penetrate the stage. The first support member may vertically penetrate the stage. The first support member is configured such that an upper end thereof protrudes from the stage to support the object to be processed. The first support member raises and lowers the object to be processed. The first support member may be driven by the drive part. The first support member may be a rod-shaped member extending vertically. The maximum distance (maximum vertical distance) between the upper end of the first support member and the object to be processed may be 2 mm or less, may be preferably 1 mm or less, and may be ideally 0 mm.

The second support member supports the cover, to raise and lower the cover. The second support member, at its upper end, may support the cover. The second support member may be a rod-shaped member extending vertically. The second support member may be disposed so as to penetrate the stage at circumferentially outward from the first support member. The second support member may vertically penetrate the stage.

The drive part is configured to raise and lower the cover supported by the second support member, between a lowered position and a raised position, by driving the second support member. The drive part may drive the second support member by being driven to move up and down by any type of actuator.

The drive part, when raising the cover from the lowered position to the raised position, is through a first process and a second process. The first process is a process in which the cover is raised from the lowered position until reaching an intermediate position (a predetermined position between the lowered position and the raised position). In the first process, the drive part raises the second support member without raising the first support member, and thus to raise the cover without raising the object to be processed. The second process is a process in which the cover is raised from the intermediate position until reaching the raised position. In the second process, the drive part raises the first support member and the second support member integrally, and thus to raise the cover from the beginning of the second process, and raise the object to be processed from the beginning of the second process or after the beginning of the second process. That is, the first support member and the second support member can be raised by the same drive part. This eliminates the necessity to separately provide a drive part for driving the first support member and a drive part for driving the second support member.

The driving unit may raise the cover, after the plasma processing of the object to be processed is completed, from the lowered position to the raised position through the first process and the second process. As described above, in the first process, the object to be processed is not raised, and the cover is raised. This widens the difference between the height position of the object to be processed and the height position of the cover. In the second process subsequent to the first process, the object to be processed and the cover are both raised. Here, in the second process, when the maximum distance between the object to be processed and the upper end of the first support member is 0 mm (i.e., there is no space between the object to be processed and the upper end of the first support member during the plasma processing), the object to be processed is raised from the beginning of the second process. On the other hand, in the second process, when the maximum distance between the object to be processed and the upper end of the first support member is greater than 0 mm (i.e., there is a little space between the object to be processed and the upper end of the first support member during the plasma processing), the object to be processed is not raised immediately upon the beginning of the second process until the first support member is raised by the above maximum distance, and after the upper end of the first support member comes in contact with the object to be processed, the object to be processed is raised together with the cover. In the state where the second process ends (the cover has reached the raised position), the object to be processed is lifted from the stage, and a wide space (hereinafter sometimes referred to as an access space) is formed between the height position of the object to be processed and the height position of the cover. This access space can be used for allowing a transfer mechanism (e.g., a transfer arm that moves in a horizontal plane) for transferring the object to be processed, to access the object to be processed. Forming the access space when the cover is in the raised position is essential for enabling the transfer mechanism to access the object to be processed.

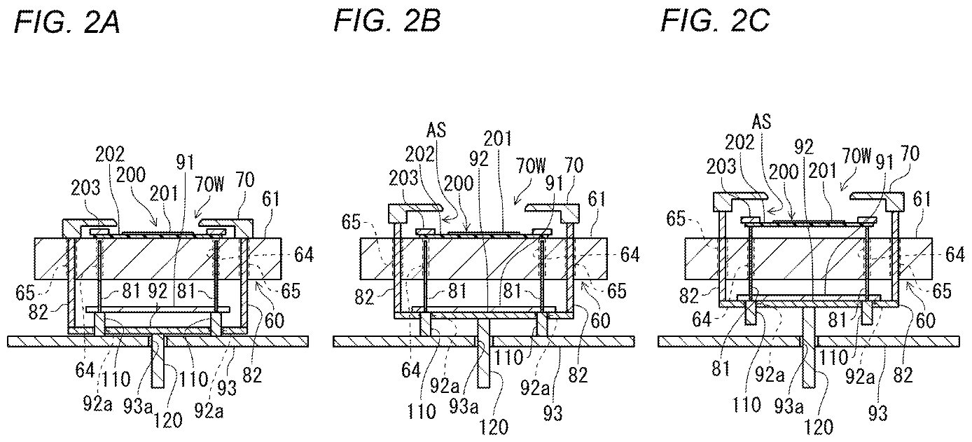

Here, in the plasma processing apparatus of Patent Literature 1, as described above, the first lifting member (corresponding to the first support member of the present disclosure) and the second lifting member (corresponding to the second support member of the present disclosure) are always raised and lowered integrally. In order to form an access space when raising the first and second lifting members in such a configuration, as shown in, for example, FIG. 2 in Patent Literature 1, it is necessary to leave a certain amount of distance (e.g., about 10 mm) between the object to be processed and the first lifting member. This distance can be a cause of abnormal discharge during the plasma processing. In contrast, in the plasma processing apparatus of the present disclosure, the first support member is not raised in the first process in which the access space is formed. Therefore, when a plasma processing is performed, the distance between the object to be processed and the first support member can be reduced (theoretically, to 0 mm). This can make an abnormal discharge unlikely to occur during the plasma processing.

The drive part may, when lowering the cover from the raised position to the lowered position, in a third process in which the cover is lowered from the raised position until reaching the intermediate position, lower the first support member and the second support member integrally, and thus to lower the object to be processed and the cover, and place the object to be processed on the stage, and in a fourth process in which the cover is lowered from the intermediate position until reaching the lowered position, lower the second support member without lowering the first support member, and thus to lower the cover, with a distance maintained between the object to be processed and the upper end of the first support member. That is, the first support member and the second support member can be lowered by the same drive part. This eliminates the necessity to separately provide a drive part for driving the first support member and a drive part for driving the second support member. When raising and when lowering the first support member and the second support member, the same drive part is driven in opposite directions.

The drive part may lower the cover, after the loading of the object to be processed into the chamber is completed, from the raised position to the lowered position through the third process and the fourth process. As described above, in the third process, the object to be processed and the cover are both lowered, and the object to be processed is placed on the stage. In this state, the access space is present. In the fourth process subsequent to the third process, the object to be processed is not lowered, and the cover is lowered. As the cover is lowered, the access space is reduced. In the state where the fourth process ends (the cover has reached the lowered position), the object to be processed is placed on the stage, and, with no access space left, the cover is sufficiently close to the object to be processed.

Here, in the plasma processing apparatus of Patent Literature 1, as described above, the first lifting member (corresponding to the first support member of the present disclosure) and the second lifting member (corresponding to the second support member of the present disclosure) are always raised and lowered integrally. In order to bring the cover sufficiently close to the object to be processed when lowering the first and second lifting members in such a configuration, as shown in, for example, FIG. 2 in Patent Literature 1, a certain amount of distance (e.g., about 10 mm) is left between the object to be processed and the first lifting member. This distance can be a cause of abnormal discharge during the plasma processing. In contrast, in the plasma processing apparatus of the present disclosure, the first support member is not lowered in the fourth process in which the cover is brought close to the object to be processed. Therefore, when a plasma processing is performed, the distance between the object to be processed and the first support member can be reduced (theoretically, to 0 mm).

The plasma processing apparatus may further include a first base which is raisable and lowerable and to which the first support member is directly or indirectly connected, and a second base which is raisable and lowerable and is disposed below the first base and to which the second support member is directly or indirectly connected. The first base may be configured to, when the cover is between the lowered position and the intermediate position, be spaced apart from the second base, and when the cover is between the intermediate position and the raised position, be raised and lowered together with the second base. According to this configuration, when the cover is between the lowered position and the intermediate position, only the second base is raised and lowered, and the first base is not raised or lowered. That is, when the cover is between the intermediate position and the raised position, only the second support member is raised and lowered, and the first support member is not raised or lowered, and thus, only the cover is raised and lowered, and the object to be processed is not raised or lowered. The second base may be driven to move up and down by the drive part. The first base may be raised by being pushed up by the rising second base. The first base may be lowered following the lowering second base. Each of the first base and the second base may be ring-shaped.

The plasma processing apparatus may further include a third base which is fixed and is disposed below the second base, and a spacer disposed between the first base and the third base. The spacer may be configured to, when the cover is between the lowered position and the intermediate position, separate the first base from the second base, with a distance maintained between the first base and the third base. According to this configuration, when the cover is between the lowered position and the intermediate position, the first base rests on the third base with the spacer therebetween. The spacer may be integral with the first base. In this case, when the cover is between the intermediate position and the raised position, the spacer is apart from the third base, and raised and lowered together with the first base and the second base. The spacer, alternatively, may be integral with the third base. In this case, the spacer stays at a fixed position regardless of the raising or lowering of the first base and the second base. Only one spacer may be provided, or a plurality of spacers may be provided.

The object to be processed may have a substrate, a holding sheet holding the substrate, and a frame supporting the holding sheet. The cover may cover the frame and an area outside the substrate in the holding sheet. The first support member may support the object to be processed, at a portion corresponding to the frame. According to this configuration, the substrate is held by the frame and the holding sheet, and the cover protects the frame and the holding sheet from plasma. The frame and the area outside the substrate in the holding sheet correspond to the outer edge portion of the object to be processed.

The object to be processed may be a substrate. The cover may cover the outer edge portion of the substrate. According to this configuration, the cover protects the outer edge portion of the substrate from plasma.

When the cover is in the lowered position, the distance between the upper end of the first support member and the object to be processed may be 1 mm or less. According to this configuration, almost no unnecessary space is formed below the object to be processed when a plasma processing is performed. This can make an abnormal discharge more unlikely to occur during the plasma processing.

(Plasma Processing Method)

A plasma processing method according to the present disclosure is performable, for example, in the above-described plasma processing apparatus, and includes a processing process and a raising process.

In the processing process, the object to be processed placed on the stage is plasma-processed. The plasma processing may be, for example, a plasma etching processing.

In the raising process, the cover supported by the second support member is raised from a lowered position to a raised position, by driving the second support member. The raising process has a first step and a second step. In the first step, the second support member is raised without raising the first support member, until the cover reaches from the lowered position to an intermediate position (a predetermined position between the lowered position and the raised position), and thus, the cover is raised without raising the object to be processed. In the first step, an access space is formed between the cover and the object to be processed. In the second step, the first support member and the second support member are raised integrally, until the cover reaches from the intermediate position to the raised position, and thus, the cover is raised from the beginning of the second step, and the object to be processed is raised from the beginning of or after the beginning of the second step.

In the plasma processing method of the present disclosure, the first support member is not raised in the first step in which the access space is formed. Therefore, when a plasma processing is performed in the processing process, the distance between the object to be processed and the first support member can be reduced (theoretically, to 0 mm). This can make an abnormal discharge unlikely to occur during the plasma processing.

The plasma processing method may further include a lowering process of lowering the cover supported by the second support member from the raised position to the lowered position, by driving the second support member. The lowering step may have a third step of lowering the first support member and the second support member integrally, until the cover reaches from the raised position to the intermediate position, thus to lower the object to be processed and the cover, and place the object to be processed on the stage, and a fourth step of lowering the second support member without lowering the first support member, until the cover reaches from the intermediate position to the lowered position, thus to lower the cover, with a distance maintained between the object to be processed and the upper end of the first support member.

In the plasma processing method according to the present configuration, the first support member is not lowered in the fourth step in which the cover is brought close to the object to be processed. Therefore, when a plasma processing is performed in the processing process, the distance between the object to be processed and the first support member can be reduced (theoretically, to 0 mm). This can make an abnormal discharge unlikely to occur during the plasma processing.

The plasma processing method may further include a replacement process of exchanging the object to be processed, between the raising process and the lowering process. After the completion of the raising process, an access space is formed between the cover and the object to be processed. In the replacement process, the processed object to be processed may be replaced with an unprocessed one, through the access space. For replacing the object to be processed, for example, a transfer arm that moves in a horizontal plane may be used. The lowering process may be performed after the replacement process is completed.

As described above, according to the present disclosure, by reducing the maximum distance between the object to be processed and the upper end of the first support member, it is possible to make an abnormal discharge unlikely to occur during the plasma processing.

In the following, examples of the plasma processing apparatus and method according to the present disclosure will be specifically described with reference to the drawings. The components and processes as described above can be applied to the components and processes of the below-described examples of the plasma processing apparatus and method. The components and processes of the below-described examples of the plasma processing apparatus and method can be modified based on the description above. The matters as described below may be applied to the above embodiments. Of the components and processes of the below-described examples of the plasma processing apparatus and method, the components and processes which are not essential to the plasma processing apparatus and method according to the present disclosure may be omitted. The figures below are schematic and not intended to accurately reflect the shape and the number of the actual members.

### Embodiment 1

Embodiment 1 of the present disclosure will be described. The following describes a plasma processing apparatus 10 first, and then, describes a plasma processing method that can be performed using the plasma processing apparatus 10.

(Plasma Processing Apparatus)

The plasma processing apparatus 10 of the present embodiment is a plasma etching apparatus, but is not limited thereto. The plasma processing apparatus 10 includes a chamber 20, a stage 60, a cover 70, a first support member 81, a second support member 82, a first base 91, a second base 92, a third base 93, a spacer 110, and a drive part 120.

The chamber 20 is configured to perform a plasma processing on an object to be processed 200, in its inside. The chamber 20 is formed in a hollow cylinder shape having an opening at the top. The chamber 20 has a bottom wall portion 21 and a sidewall portion 22 rising from the peripheral edge of the bottom wall portion 21. The opening of the chamber 20 is closed with a plate-shaped dielectric member 30. The dielectric member 30 may be made of, for example, ceramics, such as quartz, alumina, and aluminum nitride. Above the dielectric member 30, a coil 40 for generating a plasma within the chamber 20 is disposed. The coil 40 may be formed in a spiral shape.

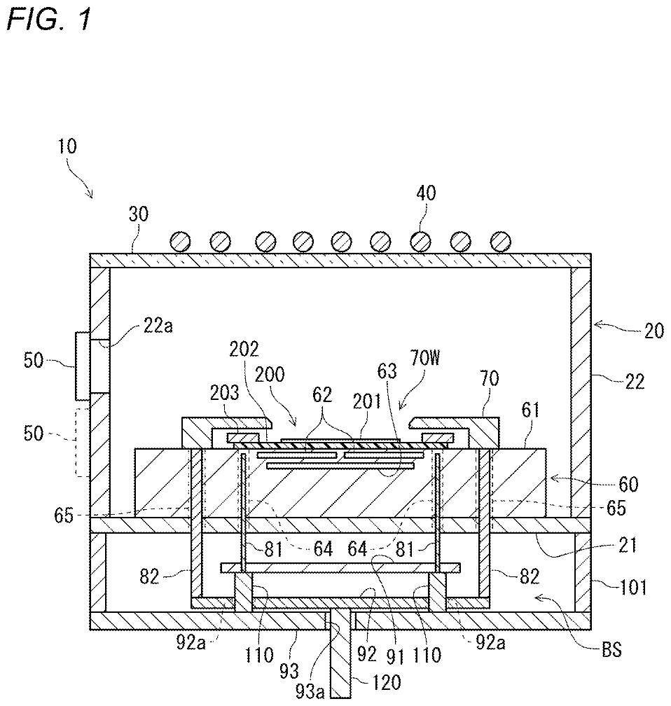

A load-unload port 22a through which the object to be processed 200 is loaded and unloaded is formed in the sidewall portion 22 of the chamber 20. This load-unload port 22a is opened and closed by a gate valve 50. The gate valve 50 is movable between a closed position (position indicated by the solid line in FIG. 1) at which the load-unload port 22a is closed and an open position (position indicated by the broken line in FIG. 1) at which the load-unload port 22a is open.

The object to be processed 200 of the present embodiment has a substrate 201, a holding sheet 202 holding the substrate 201, and a frame 203 supporting the holding sheet 202. The substrate 201 is a semiconductor substrate to be diced into individual chips by plasma etching. The holding sheet 202 is constituted of a resin sheet larger in size than the substrate 201 and has an adhesive layer for holding the substrate 201. The frame 203 is a ring-shaped member made of metal or resin, and fixed to the outer peripheral portion of the holding sheet 202.

The stage 60 is provided inside the chamber 20, and the object to be processed 200 is placed thereon. The stage 60 is fixed to the bottom wall portion 21 of the chamber 20. The stage 60 has a horizontal mounting surface 61 on which the object to be processed 200 is placed. The stage 60 has an electrostatic chuck electrode (ESC electrode) 62 for chucking the object to be processed 200. The stage 60 has a radio frequency electrode (RF electrode) 63 for controlling the energy of ions incident on the object to be processed 200. The stage 60 has a coolant channel (not shown) for cooling the object to be processed 200 during the plasma processing.

The cover 70 is provided above the stage 60. The cover 70 covers the outer edge portion of the object to be processed 200 placed on the stage 60 (in this example, the frame 203 and a region outside the substrate 201 of the holding sheet 202). The cover 70 has a window area 70W where, of the object to be processed 200 placed on the stage 60, the substrate 201 is exposed.

The first support member 81 is provided so as to vertically penetrate the stage 60. That is, a plurality of first through-holes 64 that vertically penetrate the stage 60 are formed in the stage 60, and a rod-shaped first support member 81 is inserted through each of the first through-holes 64. The first support member 81 protrudes at its upper end from the stage 60, to support the object to be processed 200. The first support member 81 of the present embodiment supports a portion corresponding to the frame 203 of the object to be processed 200. In other words, the first support member 81 of the present embodiment is disposed below the frame 203 of the object to be processed 200. The first support member 81 is vertically driven by the drive part 120, to raise and lower the object to be processed 200. The maximum distance (distance in the state as illustrated in FIG. 1) between the upper end of the first support member 81 and the object to be processed 200 is 2 mm or less, preferably 1 mm or less. A plurality (four in this example) of the first support members 81 are arranged side by side in the circumferential direction of the chamber 20, but the number and layout of the first support members 81 are not particularly limited.

The second support member 82 is provided so as to vertically penetrate the stage 60. That is, a plurality of second through-holes 65 that vertically penetrate the stage 60 are formed in the stage 60, and a rod-shaped second support member 82 is inserted through each of the second through-holes 65. The second support member 82 protrudes at its upper end from the stage 60, to support the cover 70. The second support member 82 is driven to move up and down by the drive unit 120, to raise and lower the cover 70. A plurality (four in this example) of the second support members 82 are arranged side by side in the circumferential direction of the chamber 20 at circumferentially outward from the first support member 81. However, the number and layout of the second support members 82 are not particularly limited.

The first base 91 is a plate-shaped member to which the lower end of the first support member 81 is connected. The first base 91 is disposed in a base space BS formed below the bottom wall portion 21 of the chamber 20, and is moved up and down within the base space BS. When the first base 91 is raised and lowered, the first support member 81 connected thereto is raised and lowered. In the state as illustrated in FIG. 1, the first base 91 rests on the third base 93, with the spacer 110 interposed therebetween.

The second base 92 is a plate-shaped member to which the lower end of the second support member 82 is connected. The second base 92 is disposed below the first base 91 in the base space BS. The second base 92 is moved up and down within the base space BS by the drive part 120. When the second base 92 is raised and lowered, the second support member 82 connected thereto is raised and lowered. The second base 92 has a plurality of spacer holes 92a formed therein, through each of which the spacer 110 is inserted.

The third base 93 is provided below the second base 92. The third base 93 is a fixed member and defines the base space BS together with the bottom wall portion 21 of the chamber 20 and a peripheral wall portion 101 provided therebelow. The third base 93 has, at its center, a third through-hole 93a that vertically penetrates the third base 93.

The spacer 110 is disposed between the first base 91 and the third base 93. The spacer 110 is a columnar or cylindrical member extending vertically, but the shape of the spacer 110 is not limited thereto. The spacer 110 defines the minimum vertical distance between the first base 91 and the third base 93. The spacer 110 of the present embodiment is fixed to the first base 91, and is moved up and down together with the first base 91 within the base space BS.

The drive part 120 is constituted of a rod-shaped member inserted through the third through-hole 93a. The drive part 120 is fixed to the second base 92. The drive part 120 drives the second support member 82 via the second base 92, to raise and lower the cover 70 supported by the second support member 82, between the lowered position (position shown in FIG. 1) and the raised position (position shown in FIG. 2C). The drive part 120 is driven to move up and down by any type of actuator (not shown).

As illustrated in FIGS. 2A to 2C, when the cover 70 is raised from the lowered position (position shown in FIG. 2A) to the raised position (position shown in FIG. 2C), the drive part 120 is through the first process and the second process. The first process is a process in which the cover 70 is raised from the lowered position until reaching the intermediate position (position shown in FIG. 2B). In the first process, the drive part 120 raises the second support member 82 without raising the first support member 81, thereby to raise the cover 70 without raising the object to be processed 200. In the first process, the first base 91 is spaced apart from the second base 92 and does not move. At this time, the spacer 110 maintains the distance between the first base 91 and the third base 93. The second process is a process in which the cover 70 is raised from the intermediate position until reaching the raised position. In the second process, the drive part 120 integrally raises the first support member 81 and the second support member 82, thereby to raise the cover 70 from the beginning of the second process, and raise the object to be processed 200 from the beginning of or after the beginning of the second process. In the second process, the first base 91 is raised together with the second base 92.

As illustrated in FIGS. 2A to 2C, when the cover 70 is lowered from the raised position (position shown in FIG. 2C) to the lowered position (position shown in FIG. 2A), the drive part 120 is through the third process and the fourth process. The third process is a process in which the cover 70 is lowered from the raised position until reaching the intermediate position (position shown in FIG. 2B). In the third process, the drive part 120 integrally lowers the first support member 81 and the second support member 82, thereby to lower the object to be processed 200 and the cover 70, and place the object to be processed 200 on the stage. In the third process, the first base 91 is lowered together with the second base 92. The fourth process is a process in which the cover 70 is lowered from the intermediate position until reaching the lowered position. In the fourth process, the drive part 120 lowers the second support member 82 without lowering the first support member 81, thereby to lower the cover 70, with a distance maintained between the object to be processed 200 and the upper end of the first support member 81. In the fourth process, the first base 91 is spaced apart from the second base 92 and does not move. At this time, the spacer 110 maintains the distance between the first base 91 and the third base 93.

(Plasma Processing Method)

A plasma processing method according to the present disclosure is performed using the above-described plasma processing apparatus 10. The plasma processing method may be performed using other devices or systems. The plasma processing method includes a processing process, a raising process, a replacement process, and a lowering process.

In the processing process, the object to be processed 200 (specifically, the substrate 201) placed on the stage 60 is subjected to a plasma processing (e.g., plasma etching processing).

In the raising process, the cover 70 supported by the second support member 82 is raised from the lowered position (position shown in FIG. 2A) to the raised position (position shown in FIG. 2C), by driving the second support member 82. The raising process has a first step and a second step. In the first step, the second support member 82 is raised without raising the first support member 81, until the cover 70 reaches from the lowered position to the intermediate position (position shown in FIG. 2B), and thus, the cover 70 is raised without raising the object to be processed 200. In the first step, an access space AS is formed between the cover 70 and the object to be processed 200. In the second step, the first support member 81 and the second support member 82 are raised integrally, until the cover 70 reaches from the intermediate position to the raised position, and thus, the cover 70 is raised from the beginning of the second step, and the object to be processed 200 is raised from the beginning of or after the beginning of the second step.

In the replacement process, the object to be processed 200 is replaced. In the replacement process, through the access space AS formed in the raising process, the processed object to be processed 200 is replaced with an unprocessed object to be processed 200. For replacing the object to be processed, a transfer arm that can enter and exit the chamber 20 through the load-unload port 22a in an open state.

In the lowering process, the cover 70 supported by the second support member 82 is lowered from the raised position (position shown in FIG. 2C) to the lowered position (position shown in FIG. 2A), by driving the second support member 82. The lowering process has a third step and a fourth step. In the third step, the first support member 81 and the second support member 82 are lowered integrally, until the cover 70 reaches from the raised position to the intermediate position (position shown in FIG. 2B), thereby to lower the object to be processed 200 and the cover 70, and place the object to be processed 200 on the stage 60. In the fourth step, the second support member 82 is lowered without lowering the first support member 81, until the cover 70 reaches from the intermediate position to the lowered position, thereby to lower the cover 70, with a distance maintained between the object to be processed 200 and the upper end of the first support member 81.

### Embodiment 2

Embodiment 2 of the present disclosure will be described. The present embodiment is different from the above-described Embodiment 1 in the configuration of the object to be processed 200. In the following, the difference from Embodiment 1 will be mainly described.

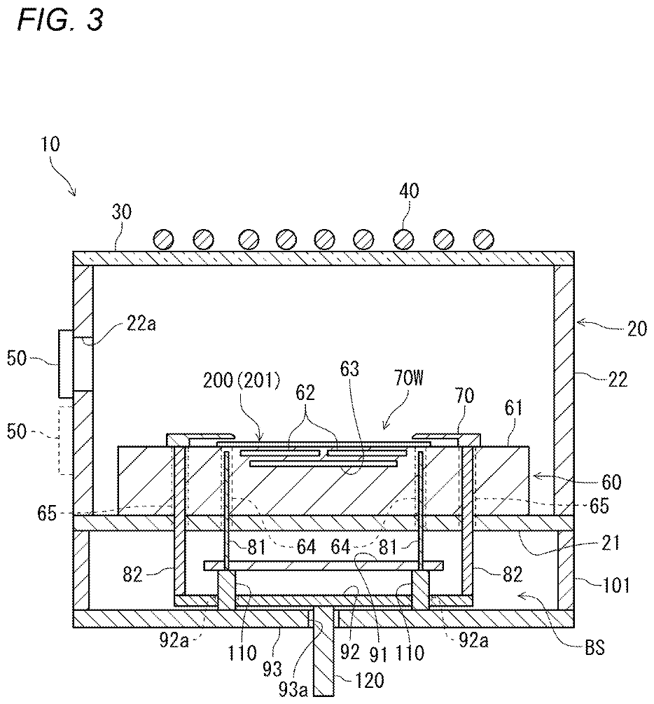

As illustrated in FIG. 3, the object to be processed 200 in the present embodiment is the substrate 201. The cover 70 covers an outer edge portion of the substrate 201. Through the window area 70W of the cover 70, a center region of the substrate 201 (a region subjected to a plasma processing) is exposed. Other configurations and operations except the above are the same as those in the above Embodiment 1.

### <<Supplementary Note>>

The following techniques are disclosed by the foregoing description of embodiments.

(Technique 1)

A plasma processing apparatus, comprising:
a chamber in which a plasma processing on an object to be processed is performed;
a stage which is disposed in the chamber and on which the object to be processed is placed;
a cover disposed above the stage and covering an outer edge portion of the object to be processed;
a first support member disposed so as to penetrate the stage, and configured such that an upper end of the first support member protrudes from the stage to support the object to be processed, to raise and lower the object to be processed;
a second support member supporting the cover, to raise and lower the cover; and
a drive part configured to raise and lower the cover supported by the second support member, between a lowered position and a raised position, by driving the second support member; wherein
the drive part, when raising the cover from the lowered position to the raised position,
in a first process in which the cover is raised from the lowered position until reaching an intermediate position between the lowered position and the raised position, raises the second support member without raising the first support member, and thus to raise the cover without raising the object to be processed, and
in a second process in which the cover is raised from the intermediate position until reaching the raised position, raises the first support member and the second support member integrally, and thus to raise the cover from a beginning of the second process, and raise the object to be processed from the beginning of the second process or after the beginning of the second process.

(Technique 2)

The plasma processing apparatus according to technique 1, wherein
the drive part, when lowering the cover from the raised position to the lowered position,
in a third process in which the cover is lowered from the raised position until reaching the intermediate position, lowers the first support member and the second support member integrally, and thus to lower the object to be processed and the cover, and place the object to be processed on the stage, and
in a fourth process in which the cover is lowered from the intermediate position until reaching the lowered position, lowers the second support member without lowering the first support member, and thus to lower the cover, with a distance maintained between the object to be processed and the upper end of the first support member.

(Technique 3)

The plasma processing apparatus according to technique 1 or 2, further comprising:
a first base which is raisable and lowerable and to which the first support member is directly or indirectly connected; and
a second base which is raisable and lowerable and is disposed below the first base and to which the second support member is directly or indirectly connected, wherein
the first base is configured to, when the cover is between the lowered position and the intermediate position, be spaced apart from the second base, and when the cover is between the intermediate position and the raised position, be raised and lowered together with the second base.

(Technique 4)

The plasma processing apparatus according to technique 3, further comprising:
a third base which is fixed and is disposed below the second base; and
a spacer disposed between the first base and the third base, wherein
the spacer is configured to, when the cover is between the lowered position and the intermediate position, separate the first base from the second base, with a distance maintained between the first base and the third base.

(Technique 5)

The plasma processing apparatus according to any one of techniques 1 to 4, wherein
the object to be processed has a substrate, a holding sheet holding the substrate, and a frame supporting the holding sheet,
the cover covers the frame and an area outside the substrate in the holding sheet, and
the first support member supports the object to be processed, at a portion corresponding to the frame.

(Technique 6)

The plasma processing apparatus according to any one of techniques 1 to 4, wherein
the object to be processed is a substrate, and
the cover covers an outer edge portion of the substrate.

(Technique 7)

The plasma processing apparatus according to any one of techniques 1 to 6, wherein when the cover is in the lowered position, a distance between the upper end of the first support member and the object to be processed is 1 mm or less.

(Technique 8)

A plasma processing method performable in a plasma processing apparatus including:
a chamber in which a plasma processing on an object to be processed is performed;
a stage which is disposed in the chamber and on which the object to be processed is placed;
a cover disposed above the stage and covering an outer edge portion of the object to be processed placed on the stage;
a first support member disposed so as to penetrate the stage, and configured such that an upper end of the first support member protrudes from the stage to support the object to be processed, to raise and lower the object to be processed; and
a second support member supporting the cover, to raise and lower the cover,
the method comprising:
a processing process of performing a plasma processing on the object to be processed placed on the stage; and
a raising process of raising the cover supported by the second support member from a lowered position to a raised position, by driving the second support member, wherein
the raising process has
a first step of raising the second support member without raising the first support member, until the cover reaches from the lowered position to an intermediate position between the lowered position and the raised position, thus to raise the cover without raising the object to be processed, and
a second step of raising the first support member and the second support member integrally, until the cover reaches from the intermediate position to the raised position, thus to raise the cover from a beginning of the second step, and raise the object to be processed from the beginning of the second step or after the beginning of the second step.

(Technique 9)

The plasma processing method according to technique 8, further comprising:
a lowering process of lowering the cover supported by the second support member from the raised position to the lowered position, by driving the second support member, wherein
the lowering process has
a third step of lowering the first support member and the second support member integrally, until the cover reaches from the raised position to the intermediate position, thus to lower the object to be processed and the cover, and place the object to be processed on the stage, and
a fourth step of lowering the second support member without lowering the first support member, until the cover reaches from the intermediate position to the lowered position, thus to lower the cover, with a distance maintained between the object to be processed and the upper end of the first support member.

(Technique 10)

The plasma processing method according to technique 9, further comprising: a replacement process of replacing the object to be processed, between the raising process and the lowering process.

The present disclosure is applicable to a plasma processing apparatus and a plasma processing method.

### REFERENCE NUMERALS

10: plasma processing apparatus
   20: chamber
      21: bottom wall portion
      22: sidewall portion
         22a: load-unload port
   30: dielectric member
   40: coil
   50: gate valve
   60: stage
      61: mounting surface
      62: ESC electrode
      63: RF electrode
      64: first through-hole
      65: second through-hole
   70: cover
      70W: window area
   81: first support member
   82: second support member
   91: first base
   92: second base
      92a: spacer hole
   93: third base
      93a: third through-hole
   101: peripheral wall portion
   110: spacer
   120: drive part
200: object to be processed
   201: substrate
   202: holding sheet
   203: frame
AS: access space
BS: base space

What is claimed is:

1. A plasma processing apparatus, comprising:
a chamber in which a plasma processing on an object to be processed is performed;
a stage which is disposed in the chamber and on which the object to be processed is placed;
a cover disposed above the stage and covering an outer edge portion of the object to be processed;
a first support member disposed so as to penetrate the stage, and configured such that an upper end of the first support member protrudes from the stage to support the object to be processed, to raise and lower the object to be processed;
a second support member supporting the cover, to raise and lower the cover; and
a drive part configured to raise and lower the cover supported by the second support member, between a lowered position and a raised position, by driving the second support member; wherein
the drive part, when raising the cover from the lowered position to the raised position,
in a first process in which the cover is raised from the lowered position until reaching an intermediate position between the lowered position and the raised position, raises the second support member without raising the first support member, and thus to raise the cover without raising the object to be processed, and
in a second process in which the cover is raised from the intermediate position until reaching the raised position, raises the first support member and the second support member integrally, and thus to raise the cover from a beginning of the second process, and raise the object to be processed from the beginning of the second process or after the beginning of the second process.

2. The plasma processing apparatus according to claim 1, wherein
the drive part, when lowering the cover from the raised position to the lowered position,
in a third process in which the cover is lowered from the raised position until reaching the intermediate position, lowers the first support member and the second support member integrally, and thus to lower the object to be processed and the cover, and place the object to be processed on the stage, and
in a fourth process in which the cover is lowered from the intermediate position until reaching the lowered position, lowers the second support member without lowering the first support member, and thus to lower the cover, with a distance maintained between the object to be processed and the upper end of the first support member.

3. The plasma processing apparatus according to claim 1, further comprising:
a first base which is raisable and lowerable and to which the first support member is directly or indirectly connected; and
a second base which is raisable and lowerable and is disposed below the first base and to which the second support member is directly or indirectly connected, wherein
the first base is configured to, when the cover is between the lowered position and the intermediate position, be spaced apart from the second base, and when the cover is between the intermediate position and the raised position, be raised and lowered together with the second base.

4. The plasma processing apparatus according to claim 3, further comprising:
a third base which is fixed and is disposed below the second base; and
a spacer disposed between the first base and the third base, wherein
the spacer is configured to, when the cover is between the lowered position and the intermediate position, separate the first base from the second base, with a distance maintained between the first base and the third base.

5. The plasma processing apparatus according to claim 1, wherein
the object to be processed has a substrate, a holding sheet holding the substrate, and a frame supporting the holding sheet,
the cover covers the frame and an area outside the substrate in the holding sheet, and
the first support member supports the object to be processed, at a portion corresponding to the frame.

6. The plasma processing apparatus according to claim 1, wherein
the object to be processed is a substrate, and
the cover covers an outer edge portion of the substrate.

7. The plasma processing apparatus according to claim 1, wherein when the cover is in the lowered position, a distance between the upper end of the first support member and the object to be processed is 1 mm or less.

8. A plasma processing method performable in a plasma processing apparatus including:
a chamber in which a plasma processing on an object to be processed is performed;
a stage which is disposed in the chamber and on which the object to be processed is placed;
a cover disposed above the stage and covering an outer edge portion of the object to be processed placed on the stage;
a first support member disposed so as to penetrate the stage, and configured such that an upper end of the first support member protrudes from the stage to support the object to be processed, to raise and lower the object to be processed; and
a second support member supporting the cover, to raise and lower the cover,
the method comprising:
a processing process of performing a plasma processing on the object to be processed placed on the stage; and
a raising process of raising the cover supported by the second support member from a lowered position to a raised position, by driving the second support member, wherein
the raising process has
a first step of raising the second support member without raising the first support member, until the cover reaches from the lowered position to an intermediate position between the lowered position and the raised position, thus to raise the cover without raising the object to be processed, and
a second step of raising the first support member and the second support member integrally, until the cover reaches from the intermediate position to the raised position, thus to raise the cover from a beginning of the second step, and raise the object to be processed from the beginning of the second step or after the beginning of the second step.

9. The plasma processing method according to claim 8, further comprising:
a lowering process of lowering the cover supported by the second support member from the raised position to the lowered position, by driving the second support member, wherein
the lowering process has
a third step of lowering the first support member and the second support member integrally, until the cover reaches from the raised position to the intermediate position, thus to lower the object to be processed and the cover, and place the object to be processed on the stage, and
a fourth step of lowering the second support member without lowering the first support member, until the cover reaches from the intermediate position to the lowered position, thus to lower the cover, with a distance maintained between the object to be processed and the upper end of the first support member.

10. The plasma processing method according to claim 9, further comprising: a replacement process of replacing the object to be processed, between the raising process and the lowering process.
